(19) United States
(12) Patent Application Publication
(10) Pub. No.: US 2017/0346054 A1
(43) Pub. Date: Nov. 30, 2017

(54) ELECTRICAL EQUIPMENT CABINETS WITH ONE OR MORE BATTERY UNIFYING CARRIERS

(71) Applicant: VERTIV ENERGY SYSTEMS, INC., Lombard, IL (US)

(72) Inventor: Jin Harrison ELKINS, LaGrange, GA (US)

(21) Appl. No.: 15/607,063

(22) Filed: May 26, 2017

Related U.S. Application Data
(60) Provisional application No. 62/342,006, filed on May 26, 2016.

(51) Int. Cl. H01M 2/10; H01M 6/42; H05K 7/14; H02B 1/56

(52) U.S. Cl. CPC H01M 2/1077; H05K 7/14; H01M 6/42; H01M 2/1016; H01M 2/1072; H02B 1/565

(57) ABSTRACT

An electrical equipment cabinet includes a plurality of walls defining an interior of the electrical equipment cabinet, a battery carrier positionable within the interior of the electrical equipment cabinet, and a plurality of batteries attached to the battery carrier via adhesive to substantially prevent removal of the plurality of batteries from the battery carrier. Other example electrical equipment cabinets, battery carriers, etc. are also disclosed.

### CROSS-REFERENCE TO RELATED APPLICATION

This application claims the benefit and priority of U.S. Provisional Application No. 62/342,006 filed May 26, 2016. The entire disclosure of the above application is incorporated herein by reference.

### FIELD

The present disclosure relates to electrical equipment cabinets with one or more battery unifying carriers.

### BACKGROUND

This section provides background information related to the present disclosure which is not necessarily prior art.

Electrical equipment cabinets such as telecommunication cabinets commonly include electrical equipment such as switches, power converters, rectifiers and batteries. Commonly, the batteries are placed physically independent of each other in the cabinets to allow removal, replacement, etc. of one battery at a time, when desired.

### SUMMARY

This section provides a general summary of the disclosure, and is not a comprehensive disclosure of its full scope or all of its features.

According to one aspect of the present disclosure, an electrical equipment cabinet includes a plurality of walls defining an interior of the electrical equipment cabinet, a battery carrier positionable within the interior of the electrical equipment cabinet, and a plurality of batteries attached to the battery carrier via adhesive to substantially prevent removal of the plurality of batteries from the battery carrier.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram of an electrical equipment cabinet including a battery carrier and two batteries attached to the battery carrier via adhesive according to one example embodiment of the present disclosure.

FIG. 2 is an isometric view of an electrical equipment cabinet including a battery carrier with adhesive placed on the battery carrier's back wall according to another example embodiment.

FIG. 3 is an isometric view of the electrical equipment cabinet of FIG. 2 including two batteries attached to the battery carrier according to yet another example embodiment.

FIG. 4 is an isometric view of an electrical equipment cabinet including a battery carrier with adhesive placed on the battery carrier's floor and back wall according to another example embodiment.

FIG. 5 is an isometric view of a battery carrier having strap attachment points for moving the battery carrier according to yet another example embodiment.

FIG. 6 is an isometric view of an electrical equipment cabinet in which a lifting device is moving the battery carrier of FIG. 5 according to another example embodiment.

FIG. 7 is a telecommunication cabinet including the battery carrier and batteries of FIG. 5 according to yet another example embodiment.

Corresponding reference numerals indicate corresponding parts and/or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

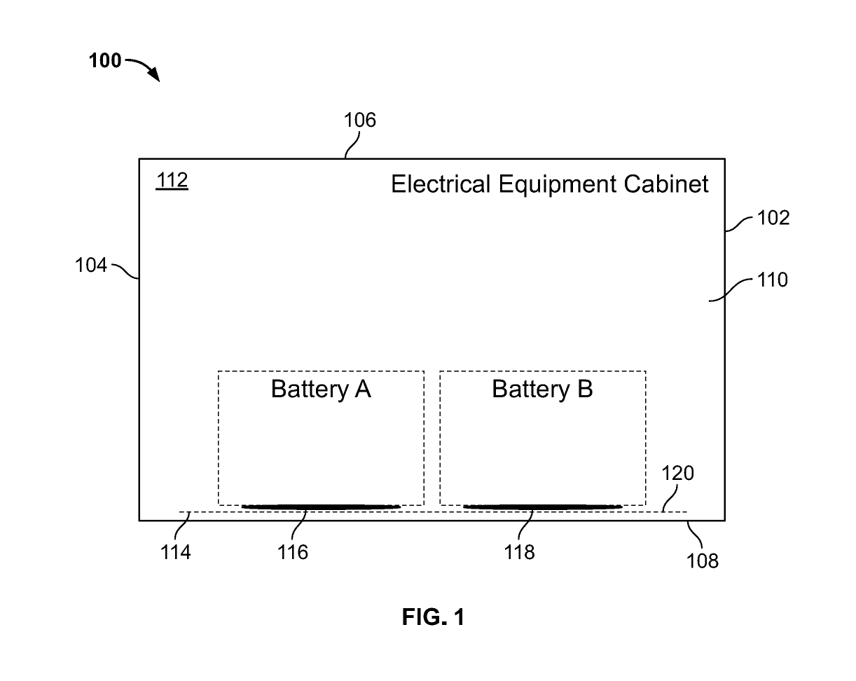

An electrical equipment cabinet according to one example embodiment of the present disclosure is illustrated in FIG. 1 and indicated generally by reference number 100. As shown in FIG. 1, the electrical equipment cabinet 100 includes walls 102, 104, 106, 108, 110 defining an interior 112 of the cabinet 100, a battery carrier 114 positioned within the interior 112 of the cabinet 100, and two batteries A, B attached to the battery carrier 114 via adhesive(s) 116, 118 to substantially prevent removal of the batteries A, B from the battery carrier 114.

By attaching the batteries A, B to the battery carrier 114, individuals may be deterred and, in some cases, prohibited from unlawfully removing the batteries A, B from the cabinet 100. For example, when batteries (e.g., the batteries A, B and/or other batteries disclosed herein, etc.) are coupled to a battery carrier (e.g., the battery carrier 104 or another one of the battery carriers disclosed herein), a unified set of batteries is created. This unified set of batteries weighs more than individual batteries thereby making removal of the unified set of batteries more difficult than removal of individual batteries. As a result, an individual attempting to unlawfully remove the batteries from the cabinet may be deterred or prevented from removing the batteries due to the weight of the unified set of batteries. In turn, the cost of replacing batteries, fixing damaged components, etc. may be reduced and, in some cases, eliminated.

In some embodiments, the unified set of batteries may weigh about 500 pounds or more whereas each individual battery may weigh up to about 150 pounds. More particularly, the unified set of batteries may weigh up to 700 pounds or more depending on, for example, the type of batteries used, material of the battery carrier, etc. As such, removal of the unified set of batteries from the cabinet may require specialized equipment (e.g., a crane, a hoist, etc.), multiple individuals, etc.

The battery carrier 114 of FIG. 1 includes a single wall (e.g., a floor) 120 for supporting the batteries A, B. As shown in FIG. 1, the batteries A, B are attached to the floor 120 of the battery carrier 114 via the adhesives 116, 118. As such, the batteries A, B are attached to the same wall of the battery carrier 114. The adhesives 116, 118 may be applied to the floor 120 prior to the placing the batteries A, B on the battery carrier 114. Alternatively, or additionally, the adhesives 116, 118 may be applied to the batteries A, B prior to the placing the batteries A, B on the battery carrier 114. In either case, the adhesives 116, 118 are positioned between the batteries A, B and the battery carrier 114 (e.g., the floor 120) when the batteries A, B are attached to the battery carrier 114.

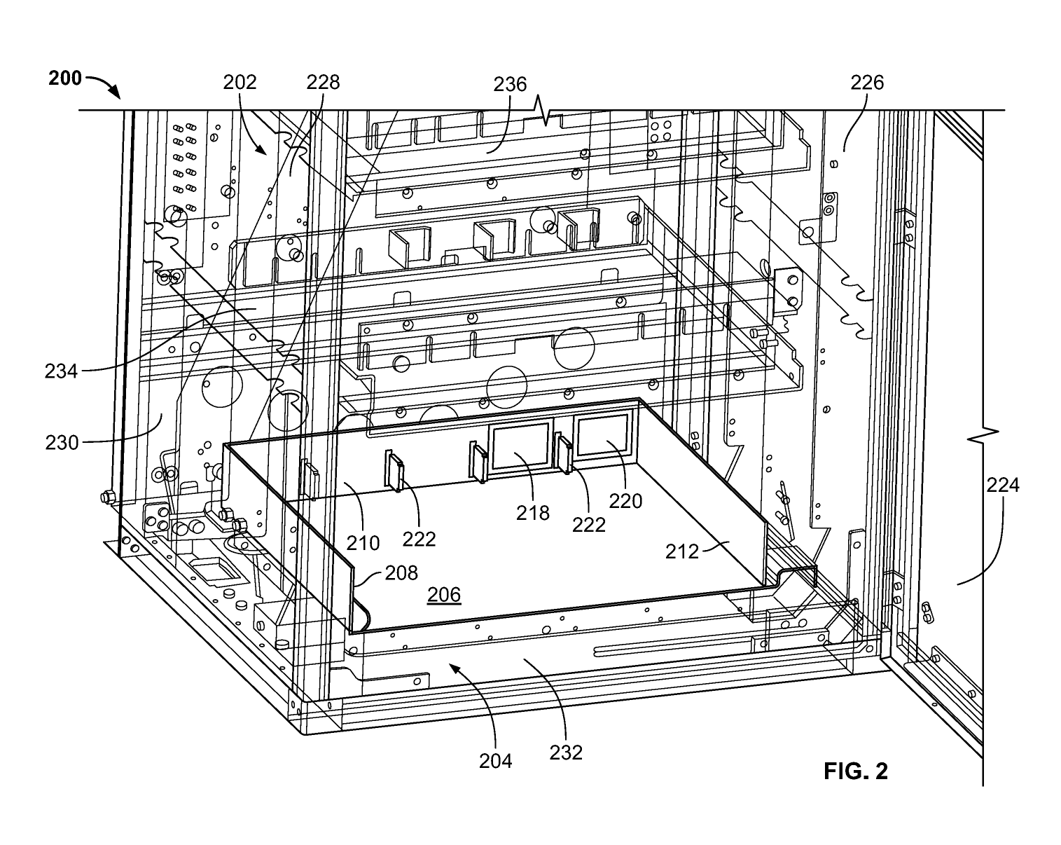

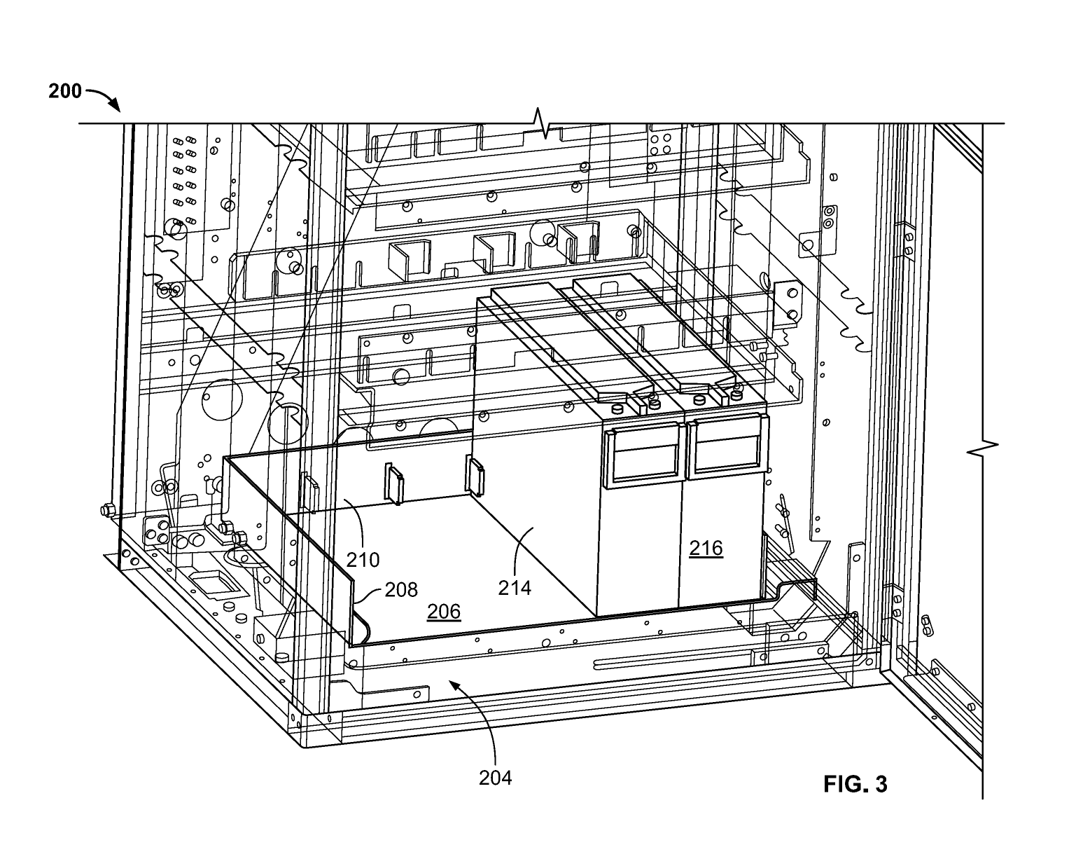

In other embodiments, the battery carrier 114 may include one or more additional and/or alternate walls. For example, FIGS. 2 and 3 illustrate a portion of an electrical equipment cabinet 200 including walls defining an interior 202 of the cabinet 200, and a battery carrier 204 positioned in the interior 202 of the cabinet 200. As shown in FIGS. 2 and 3, the battery carrier 204 includes four walls 206, 208, 210, 212. In particular, the wall 206 of the battery carrier 204 is a floor for supporting batteries 214, 216 (as shown in FIG. 3). The walls 208, 210, 212 are three side walls of the battery carrier 204 extending from the floor 206 for defining a partially enclosed area for receiving the batteries 214, 216 (and other batteries not shown). As shown, the floor 206 and the side walls 208, 210, 212 create an opening for receiving the batteries 214, 216.

Although the battery carrier 204 is shown to include four walls 206, 208, 210, 212, it should be apparent that the battery carrier 204 may include more or less walls if desired. For example, the battery carrier 204 may include a wall (e.g., a ceiling) extending across at least a portion of the area for receiving the batteries 214, 216, a side wall extending between the side walls 208, 212, etc.

In the particular example of FIGS. 2 and 3, two strips 218, 220 of adhesive are applied to the rear side wall 210 of the battery carrier 204 prior to installation of the batteries 214, 216. After which, the batteries 214, 216 are inserted into the battery carrier 204 and pressed against its corresponding strips 218, 220 of adhesive to attach the batteries 214, 216 to the rear side wall 210 of the battery carrier 204. In other embodiments, the strips 218, 220 of adhesive may be coupled to the sides of the batteries, as explained above. For example, the strips 218, 220 of adhesive may be coupled to rear sides of battery cases storing the batteries 214, 216. The battery cases may then be pressed against the rear side wall 210, as explained above. In either example, the strips 218, 220 of adhesive are coupled between the rear side wall 210 and the batteries 214, 216 when the batteries are installed. Thus, the batteries 214, 216 are attached to the back side wall 210 of the battery carrier 204 via the strips 218, 220 of adhesive, as shown in FIGS. 2 and 3.

This allows the batteries 214, 216 to attach to the battery carrier 204 at the wall 210 opposing an access point (e.g., a door 224) of the cabinet 200. In particular, the floor 206 of the battery carrier 204 is positioned between the rear side wall 210 and the door 224 of the electrical equipment cabinet 200. This configuration may provide a greater deterrent to individuals attempting to unlawfully remove the batteries because the strips 218, 220 of adhesive used to attach the batteries 214, 216 to the battery carrier 204 may be blocked from view, difficult to reach, etc.

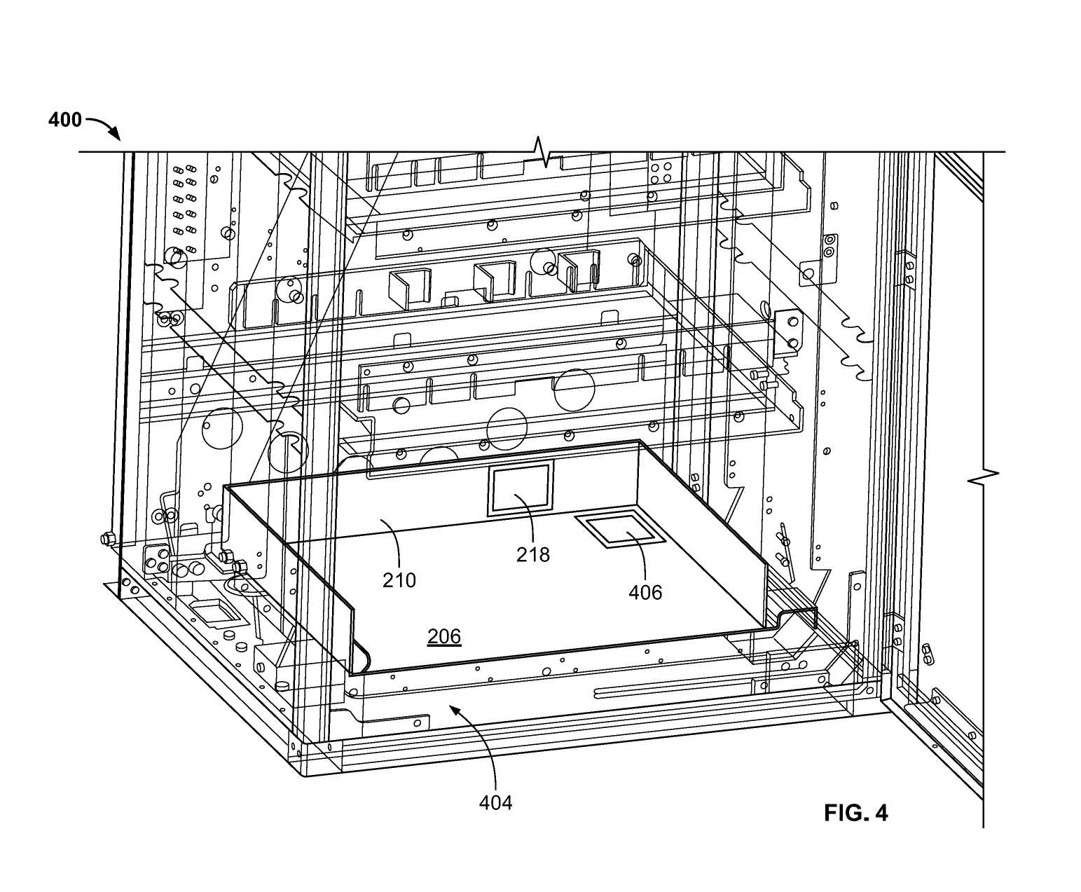

In other embodiments, the strips 218, 220 of adhesive may be placed on different walls of the battery carrier 204. As such, the batteries 214, 216 may be attached to different walls of the battery carrier 204. For example, FIG. 4 illustrates a portion of a cabinet 400 including a battery carrier 404 substantially similar to the battery carrier 204 of FIGS. 2 and 3. For instance, the battery carrier 404 includes the floor 206, the rear side wall 210 extending from the floor 206, and the strip 218 of adhesive placed on the rear side wall 210. The battery carrier 404, however, also includes a strip 406 of adhesive on the floor 206. As such, when batteries are attached to the battery carrier 404, one battery is attached to the rear side wall 210 of the battery carrier 404 via the strip 218 of adhesive, and another battery is attached to the floor 206 of the battery carrier 404 via the strip 406 of adhesive.

Additionally, and as shown in FIGS. 2 and 3, the battery carrier 204 may optionally include divider walls 222 extending from the rear side wall 210. These divider walls 222 define slots for receiving batteries including the batteries 214, 216. The divider walls 222 may assist a user in aligning and positioning the batteries 214, 216 in the slots of the battery carrier 204, may maintain a desired clearance between the adjacent batteries 214, 216 to allow for thermal expansion of the batteries, etc. In other embodiments, the battery carrier 204 may include additional divider walls extending from another wall. For example, the battery carrier 204 may include one or more divider walls extending from the floor 206 in addition to and/or alternative to the divider walls 222.

The battery carrier 204 of FIGS. 2 and 3 includes four divider walls 222 that define five slots. As such, the battery carrier 204 of FIGS. 2 and 3 may accommodate up to five batteries. Alternatively, the battery carrier 204 may include more or less divider walls 222 to define more or less slots for accommodating a different number of batteries. In some embodiments, the battery carrier 204 may not include divider walls. For example, as shown in FIG. 4, the battery carrier 404 does not include divider walls. In such examples, a single piece of adhesive may be employed to attach two or more batteries to the battery carrier 404.

Referring back to FIGS. 2 and 3, the cabinet 200 includes various vertical extending walls (e.g., exterior walls, partitions, etc.) and horizontal extending walls (e.g., a base, a ceiling, partitions, etc.) coupled together to define the interior 202 of the cabinet 200, as explained above. For example, FIGS. 2 and 3 illustrate vertical walls 224, 226, 228, 230, a base 232, and two horizontal partition walls 234, 236. In the particular example of FIGS. 2 and 3, the wall 224 is a door pivotably coupled to the wall 226 to allow access to the interior 202 of the cabinet 200. Although not shown, it should be apparent that the cabinet 200 and/or other cabinets disclosed herein may include other walls including, for example, a ceiling, vertical partition walls, etc. Additionally, although the cabinet 200 is shown to include two horizontal partition walls 234, 236, the cabinet 200 may include more or less horizontal partition walls if desired.

As shown in FIGS. 2 and 3, the battery carrier 204 is positioned adjacent to the bottom of the cabinet 200. In particular, the battery carrier 204 is positioned between the base 232 and the horizontal partition wall 234. In other embodiments, the battery carrier 204 may be positioned in another suitable location and/or one or more additional battery carriers may be placed in the cabinet 200. For example, the battery carrier 204 may be positioned between the horizontal partition walls 234, 236 if desired.

In some embodiments, any one of the battery carriers disclosed herein may include one or more fasteners for coupling to a lifting device to move the battery carrier. As such, the battery carrier and the batteries attached to the battery carrier (collectively a unified set of batteries) may be moved into, removed from, etc. an electrical equipment cabinet (e.g., the cabinet 200 of FIGS. 2 and 3, etc.) as a single unit.

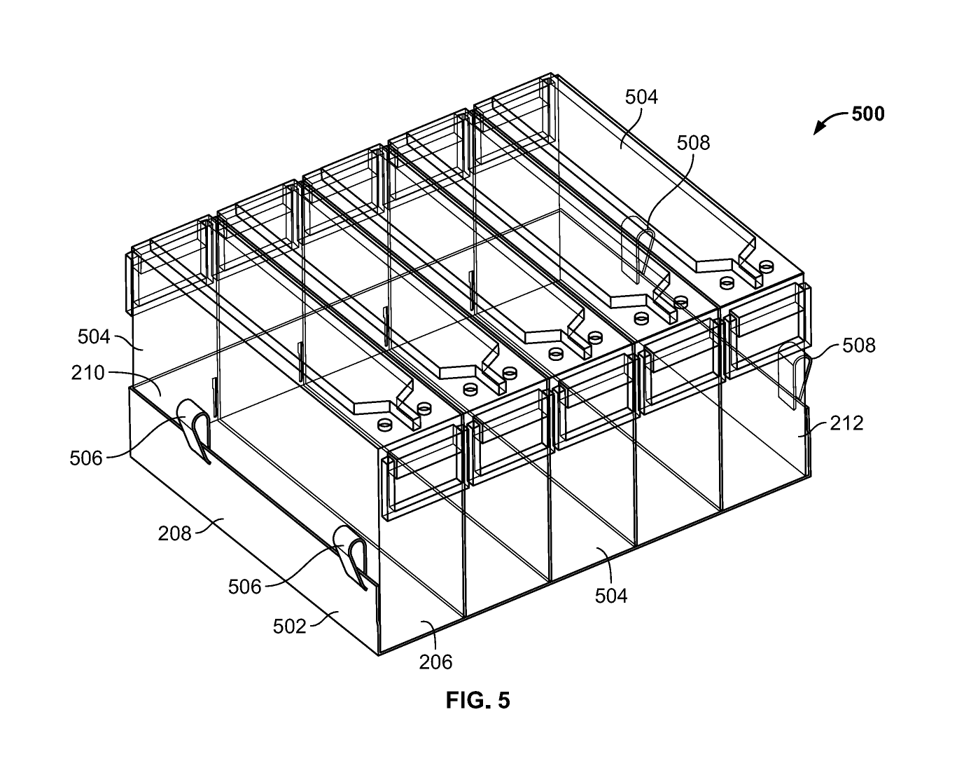

For example, FIG. 5 illustrates a unified set of batteries 500 including a battery carrier 502 and five batteries 504 attached to the battery carrier 502, as explained herein. The battery carrier 502 is substantially similar to the battery carrier 204 of FIGS. 2 and 3 and the battery carrier 404 of FIG. 4. For example, the battery carrier 502 includes the floor 206 and the side walls 208, 210, 212 of FIGS. 2 and 3. The battery carrier 502, however, also includes four fasteners coupled to the side walls 208, 212. In particular, the battery carrier 502 includes two strap attachment points 506 coupled to the side wall 208 and two strap attachment points 508 coupled to the side wall 212. Additionally and/or alternatively, the battery carrier 502 may include other suitable flexible and/or rigid fasteners (e.g., clamps, clips, hooks, bolts such as eye bolts, etc.), more or less strap attachment points 506, 508, etc. coupled to the side walls 208, 210, 212 and/or the floor 206 to assist a user in moving the unified set of batteries 500. In some embodiments, the type of fasteners utilized may depend on, for example, the weight of the unified set of batteries 500, the fastener material, etc.

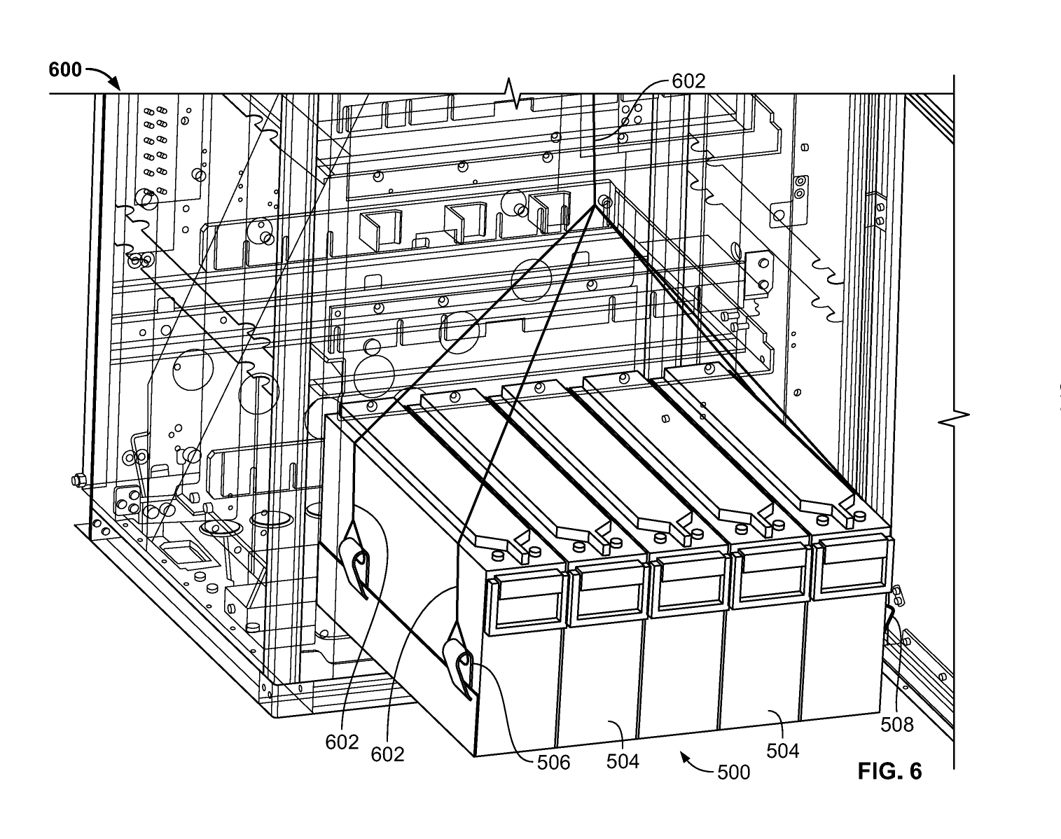

The strap attachment points 506, 508 and/or other suitable fasteners may be used to install and/or remove the unified set of batteries 500 into and/or out of an electrical equipment cabinet (e.g., the cabinet 200 of FIGS. 2 and 3, etc.). For example, and as shown in FIG. 6, the unified set of batteries 500 may be detachably coupled to a lifting device to move the unified set of batteries 500 into and/or out of an electrical equipment cabinet 600. The cabinet 600 may be substantially similar to the cabinets 100, 300, 400 of FIGS. 1-4. The lifting device may include a crane, a hoist, etc. and a lifting medium 602 (e.g., cables, ropes, chains, etc.) detachably coupled to the strap attachment points 506, 508 for moving the unified set of batteries 500. In the particular example of FIG. 6, the lifting medium 602 includes one or more cables.

For example, and with reference to FIGS. 5 and 6, during the installation process, the batteries 504 may be attached to the battery carrier 502 which is installed in an electrical equipment cabinet to create the unified set of batteries 500. Alternatively, the batteries 504 may be coupled to the battery carrier 502 before the battery carrier 502 is installed in the cabinet. In such examples, a user can utilize the strap attachment points 506, 508 to move and install the unified set of batteries 500 as a single unit.

If one or more of the batteries 504 of the unified set of batteries 500 fail, the entire unified set of batteries may be removed as a unit from the cabinet and replaced. For example, the installed unified set of batteries 500 may be removed with a lifting device including the one or more cables 602, as explained above. After which, a new battery carrier, a new unified set of batteries (including a battery carrier), etc. can be placed into the cabinet.

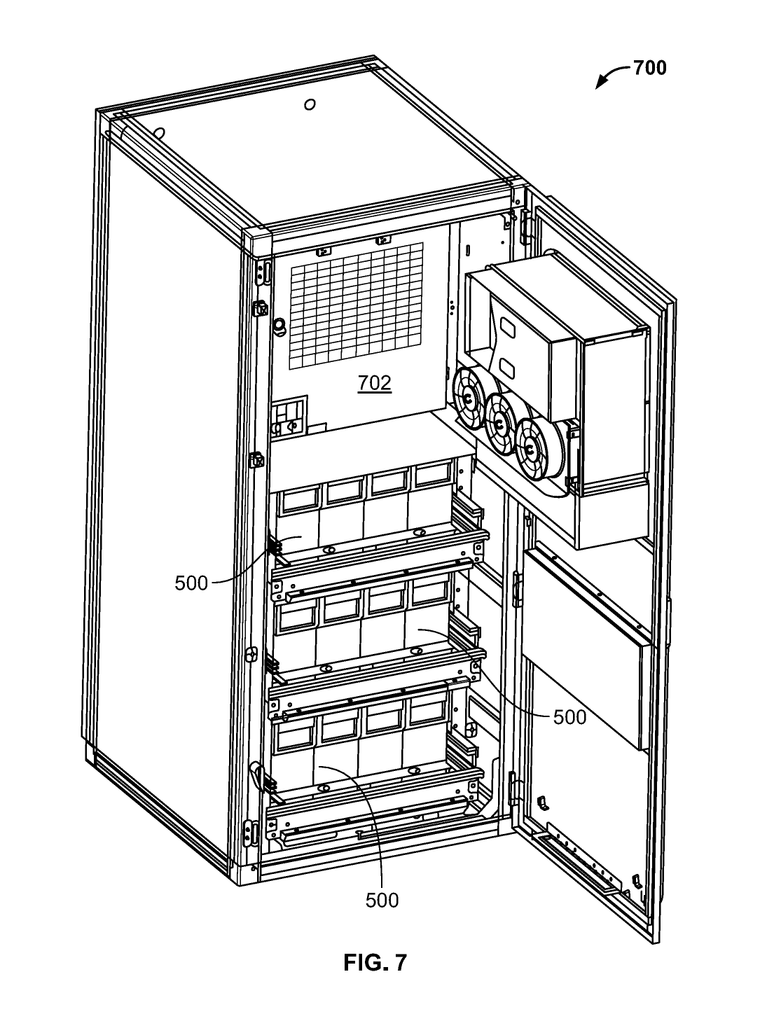

The electrical equipment cabinets disclosed herein may be used in different applications including, for example, outside plant (OSP) applications, indoor applications, etc. In some embodiments, the cabinets are used in telecommunication applications, information technology applications, etc. For example, FIG. 7 illustrates an electrical equipment cabinet 700 for use in telecommunication applications. As shown in FIG. 7, the cabinet 700 includes a chamber 702 (e.g., a sealed chamber, etc.) for storing electrical equipment such as one or more power converters, rectifiers, switches, control circuits, etc., three unified sets of batteries, and a heat exchanger 704 coupled to a door of the cabinet 700. In the particular example of FIG. 7, the unified sets of batteries are shown as the unified set of batteries 500 of FIG. 5. In other examples, one or more other suitable unified sets of batteries may be employed in addition to and/or instead of the unified sets of batteries 500.

The adhesives disclosed herein may include various suitable types of adhesive. For example, the adhesives may include a wet adhesive, doubled sided tape, etc. depending on, for example, the battery (e.g., the battery casing) material, the battery carrier material, etc. If a wet adhesive is used, the adhesive may cure when the moisture in the adhesive has evaporated. The adhesives may be rolled, painted, etc. onto the battery carriers, the battery casing, etc. to form regions (e.g., strips, masses, etc.) of adhesive. In some embodiments, a silicone adhesive such as a room temperature vulcanization (RTV) silicone adhesive is preferred. For example, the strips 218, 220 of adhesive shown in FIG. 2 may be strips of silicone adhesive.

The batteries disclosed herein may include any suitable type of battery. For example, one or more of the batteries may be rechargeable batteries such as lead-acid batteries, nickel cadmium (NiCd) batteries, nickel metal hydride (NiMH) batteries, lithium ion (Li-ion) batteries, etc. Additionally, adjacent batteries in one unified set of batteries may be attached together to provide added strength. This may occur before and/or after the batteries are attached to their corresponding battery carrier. For example, adjacent batteries may be coupled together via one or more adhesives, mechanical fasteners and/or other suitable coupling devices.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An electrical equipment cabinet comprising:
a plurality of walls defining an interior of the electrical equipment cabinet;
a battery carrier positionable within the interior of the electrical equipment cabinet; and
a plurality of batteries attached to the battery carrier via adhesive to substantially prevent removal of the plurality of batteries from the battery carrier.

2. The electrical equipment cabinet of claim 1 wherein the plurality of batteries are attached to the battery carrier without mechanical fasteners.

3. The electrical equipment cabinet of claim 1 wherein the plurality of batteries are attached to the battery carrier via only the adhesive.

4. The electrical equipment cabinet of claim 1 wherein the battery carrier includes one or more walls and wherein the plurality of batteries are attached to at least one of the one or more walls of the battery carrier via the adhesive.

5. The electrical equipment cabinet of claim 4 wherein the one or more walls of the battery carrier include a floor for supporting the plurality of batteries and at least one side wall extending from the floor, and wherein the at least one of the one or more walls is the at least one side wall.

6. The electrical equipment cabinet of claim 5 wherein the plurality of walls of the electrical equipment cabinet includes a door and wherein the floor of the battery carrier is positioned between the at least one side wall and the door of the electrical equipment cabinet.

7. The electrical equipment cabinet of claim 6 wherein the battery carrier includes one or more divider walls extending from the at least one side wall to define a plurality of slots, and wherein the plurality of batteries are positioned in the plurality of slots of the battery carrier.

8. The electrical equipment cabinet of claim 1 wherein the battery carrier includes two or more walls, and wherein the plurality of batteries include a first battery attached to one of the two or more walls of the battery carrier via the adhesive and a second battery attached to another one of the two or more walls of the battery carrier the adhesive.

9. The electrical equipment cabinet of claim 8 wherein the two or more walls of the battery carrier include a floor for supporting the plurality of batteries and a side wall extending from the floor, wherein said one of the two or more walls of the battery carrier is the floor of the battery carrier, and wherein said another one of the two or more walls of the battery carrier is the side wall of the battery carrier.

10. The electrical equipment cabinet of claim 1 wherein the adhesive includes silicone adhesive.

11. The electrical equipment cabinet of claim 1 wherein the battery carrier includes one or more fasteners configured to couple to a lifting device to move the battery carrier.

12. The electrical equipment cabinet of claim 11 wherein the one or more fasteners includes one or more straps.

13. The electrical equipment cabinet of claim 11 wherein the battery carrier includes a floor for supporting the plurality of batteries and two or more side walls extending from the floor, and wherein the one or more fasteners are coupled to the two or more side walls of the battery carrier.

14. The electrical equipment cabinet of claim 1 wherein the battery carrier and the plurality of batteries are removable as a unit from the electrical equipment cabinet.
